(19) United States
(12) Patent Application Publication
(10) Pub. No.: US 2025/0008704 A1
(43) Pub. Date: Jan. 2, 2025

(54) SYSTEMS AND METHODS FOR COOLING ENCLOSURE CONTROL AND ADAPTIVE LEARNING

(71) Applicant: Dynamic Data Centers Solutions, Inc., St. Louis, MO (US)

(72) Inventor: Victor Kenneth Grover, Valley Center, CA (US)

(73) Assignee: Dynamic Data Centers Solutions, Inc., St. Louis, MO (US)

(21) Appl. No.: 18/759,462

(22) Filed: Jun. 28, 2024

Related U.S. Application Data
(60) Provisional application No. 63/510,939, filed on Jun. 29, 2023.

(51) Int. Cl. H05K 7/20; G06N 5/04

(52) U.S. Cl. CPC H05K 7/20836; G06N 5/04; H05K 7/20736

(57) ABSTRACT

Systems and methods are directed toward adaptive control systems that may be implemented with cooling systems, such as cooling cabinet enclosures. Historical operating data may be used to establish current operating parameters and then sensor readings may be used to measure performance against one or more metrics. Comparisons of the one or more metrics against metrics for the historical operating data may then be used to continuously update operating conditions when current conditions exceed historical operating conditions.

### CROSS-REFERENCE TO RELATED APPLICATIONS

This application claims priority to and the benefit of U.S. Provisional Patent Application No. 63/510,939, titled “LOGICAL ADAPTIVE CONTROL DEVICE,” filed Jun. 29, 2023, the full disclosure of which is hereby incorporated by reference in its entirety for all purposes.

### BACKGROUND

Computer equipment and related support equipment may be housed in “racks.” Facilities known as datacenters may be used to house and manage multiple racks, which may be used in a variety of applications, such as distributed computing applications. In operation, the electronic equipment may be considered heat generating components that emit heat responsive to electrical energy used to perform one or more tasks. These components may have particular operational parameters, for example high temperature parameters, and/or operational setpoints based on efficiency determinations. As a result, datacenters and their associated racks are often cooled such that heat may be dissipated away from the electronic components to enable continued operation of the computer equipment according to one or more parameters.

Often, air cooling is used to remove heat from the racks and/or individual electronics components. For example, external air flow may be directed into an enclosure that functions to remove or otherwise carry heated air away from the electronic components. In certain configurations, datacenters may be configured to distribute air among a number of racks of electronic components using a centralized fan (or blower). For example, air within the datacenter may pass through a heat exchanger for cooling the air (e.g., an evaporator of a vapor-compression cycle refrigeration cooling system or “vapor-cycle” refrigeration) or a chilled water coil. In some datacenters, the heat exchanger is mounted to the rack to provide “rack-level” cooling of air. In other datacenters, the air is cooled before entering the datacenter.

In general, a lower air temperature in a datacenter allows each electronic component to dissipate a higher power (e.g., lower air temperature will facilitate greater cooling). Consequently, datacenters have traditionally used sophisticated air conditioning systems (e.g., chillers, vapor-cycle refrigeration, etc.) to cool the air (e.g., to about 65° F.) within the datacenter for achieving a desired performance level. In general, spacing heat-dissipating components from each other (e.g., reducing heat density) makes cooling such components less difficult and hence less costly than placing the same components placed in close relation to each other (e.g., increasing heat density). Datacenters have also compensated for increased power dissipation (corresponding to increased server performance) by increasing the spacing between adjacent servers. However, it is inefficient to cool larger areas that are necessitated by increasing distance between racks.

Control systems have been used to increase cooling rates for a plurality of electronic components in response to increased computational demand. Even so, such control systems have controlled cooling systems that dissipate heat into the datacenter building interior air (which in turns needs to be cooled by air conditioning), or directly use refrigeration as a primary mode of heat dissipation. Refrigeration as a primary mode of cooling, directly or indirectly, requires significant amounts of energy.

As datacenters increase in size and components are designed to consume additional energy and/or handle greater loads, the amount of energy used to cool datacenters and associated components has increased. Additionally, high density facilities to support various processing applications, such as artificial intelligence (AI) processing, also leads to additional energy consumption, and as a result, more cooling load. One approach to larger datacenter loads has been to increase density of the datacenter, for example, adding additional components to racks. Certain high density racks may require more than 50 kW per rack. As discussed, traditional methods include cooling an entire building and exchanging the air from hot and cold isles into the atmosphere while sustaining strict conditions of air quality. Such an approach consumes large amounts of energy, increases carbon emissions, and overall increases an environmental footprint for the industry.

### SUMMARY

Applicant recognized the problems noted above herein and conceived and developed embodiments of systems and methods, according to the present disclosure, for systems and methods for cooling enclosure control and monitoring.

In an embodiment, a computer-implemented method includes receiving one or more current operating parameters for a cabinet enclosure associated with cooling one or more electronic components. The method also includes receiving one or more historical operating parameters corresponding to a desired set of operating parameters based, at least in part, on one or more current conditions of the cabinet enclosure. The method further includes determining, based on the desired set of operating parameters, one or more adjustments to the one or more current operating parameters. The method also includes applying the one or more adjustments to the one or more current operating papers to cause operation of the cabinet enclosure at one or more updated operating parameters. The method further includes determining, for the one or more updated operating parameters, one or more metrics. The method also includes comparing the one or more metrics to one or more associated metrics for the desired set of operating parameters. The method includes determining at least one metric of the one or more metrics exceeds at least one associated metric of the one or more associated metrics. The method also includes updating a corresponding operating parameter for the at least one associated metric to correspond to an updated operating parameter corresponding to the at least one metric.

In an embodiment, a computer-implemented method includes receiving sensor data corresponding to a control parameter for a cabinet enclosure. The method also includes determining one or more metrics based, at least in part, on at least a portion of the sensor data. The method further includes comparing the one or more metrics to one or more threshold operating parameters. The method also includes determining the one or more metrics fail to satisfy one or more conditions of the one or more threshold operating parameters. The method further includes causing a change in one or more current operating settings associated with the control parameter for the cabinet enclosure. The method also includes determining, following a period of time after the change, one or more updated metrics based, at least in part, on at least an updated portion of updated sensor data. The method further includes determining the one or more updated metrics satisfy the one or more conditions for the one or more threshold operating parameters. The method includes causing operation of the cabinet enclosure in accordance with the one or more operating settings including the change.

In an embodiment, a system includes at least one processor and memory. The memory includes instructions that, when executed by the at least one processor, cause the system to: receive sensor data corresponding to a control parameter for a cabinet enclosure; determine one or more metrics based, at least in part, on at least a portion of the sensor data; compare the one or more metrics to one or more threshold operating parameters; determine the one or more metrics fail to satisfy one or more conditions of the one or more threshold operating parameters; cause a change in one or more current operating settings associated with the control parameter for the cabinet enclosure; determine, following a period of time after the change, one or more updated metrics based, at least in part, on at least an updated portion of updated sensor data; determine the one or more updated metrics satisfy the one or more conditions for the one or more threshold operating parameters; and cause operation of the cabinet enclosure in accordance with the one or more operating settings including the change.

### BRIEF DESCRIPTION OF THE DRAWINGS

Various embodiments in accordance with the present disclosure will be described with reference to the drawings, in which:

FIG. 1 illustrates an example schematic representation of a cooling configuration including a cabinet enclosure in accordance with various embodiments.

FIG. 2 illustrates an example control system for a cooling configuration in accordance with various embodiments.

FIG. 3A illustrates a graphical representation of an embodiment of a cooling evaluation metric in accordance with various embodiments.

FIG. 3B illustrates a graphical representation of an embodiment of a cooling evaluation metric in accordance with various embodiments.

FIG. 3C illustrates an example process for adjusting operating conditions for a cabinet enclosure in accordance with various embodiments.

FIG. 3D illustrates an example control system for a cooling configuration in accordance with various embodiments.

FIG. 4A illustrates an example schematic representation of a cooling configuration including a cabinet enclosure in accordance with various embodiments.

FIG. 4B illustrates an example process for adjusting operating conditions for a cabinet enclosure in accordance with various embodiments.

FIG. 5A illustrates an example schematic representation of a cooling configuration including a cabinet enclosure in accordance with various embodiments.

FIG. 5B illustrates an example process for adjusting and updating operating conditions for a cabinet enclosure in accordance with various embodiments.

FIG. 6 illustrates an example process for adjusting an operating conditions for a cabinet enclosure in accordance with various embodiments.

FIG. 7 illustrates an example process for monitoring operating conditions for a cabinet enclosure in accordance with various embodiments.

FIG. 8 illustrates components of an example computing device that can be used to perform aspects of the various embodiments.

### DETAILED DESCRIPTION

Systems and methods of the present disclosure may be directed toward one or more control systems, which may include one or more control algorithms, for regulating cooling of one or more enclosures, which may be associated with a datacenter. In at least one embodiment, systems and methods may be directed toward techniques for removing heat from the datacenter environment and its components. Various embodiments of the present disclosure may be directed toward a control algorithm that learns, compares, interprets, adjust, records, controls, and displays analytical data in a corresponding graphic representing an environment. Furthermore, in at least one embodiment, the control algorithm may be configured to display one or more logical graphics to provide an interactive experience to view and interact with the graphic, graphical digitals, logical codes to control set points, and/or the like. Systems and methods may be directed toward one or more control systems to interpret and restructure data and then provide the data for access through one or more network connections, for example as browser connection to enable live data monitoring and adjustment. In at least one embodiment, systems and methods are directed toward an adaptive learning algorithm that captures histories from environmental components, generates trends or other inferences from the histories, and then adjusts various control parameters in accordance with comparisons or other evaluations to the trends. By way of example, a “most favorable” or “best” history may be identified and then parameters may be adjusted to match the conditions that provided the most favorable history. In at least one embodiment, improvements may then replace the previous most favorable history to provide a new set of parameters for operation of various components. Systems and methods may also be directed toward balancing and/or adjusting parameters in accordance with efficiency metrics or thresholds. Various embodiments may also deploy predictive analysis of various components to determine whether operating parameters, for example compared to historical parameters, are indicative of one or more upcoming failures or maintenance operations. For example, one or more embodiments may use histories to calculate if operations or components are diminishing in their mechanics, how long the operations or components have been diminishing for, etc. and then transmit one or more predictive alerts. Providing alerts in advance or failures or when an indication of an impending failure is recognized may provide time to address the failure in a proactive, rather than reactive, manner.

Various embodiments of the present disclosure are directed toward systems and methods to address and overcome problems with datacenter center cooling, and in certain embodiments, with enclosure-based datacenter cooling. The datacenter cooling challenge is actually a heat removal challenge. From a heat removal and energy perspective, embodiments of the present disclosure have recognized and implemented improvements to redesign traditionally inert systems to be dynamic, with abilities to handle varying densities, as well as fluctuating power inducements. For example, while traditional systems were associated with cooling racks with stable, lower power densities (e.g., approximately 3 to 5 kW), modern systems have much higher power densities and greater fluctuations, which may be based on different load requirements. Accordingly, air-cooled datacenters using chillers and computer room air conditioning (CRAC) units that were once sufficient to overcome the heat dissipation from the servers are no longer sufficient. Embodiments also address problems with more modern systems, such as raised floor systems and hot/cold aisle configurations. For example, even with newer systems, whole-spaces are cooled, such as by directing cold air through perforated tiles toward a cold aisle and then cooling through server racks and ejecting air into a hot aisle. Systems and methods of the present disclosure address and overcome the deficiencies of current systems by targeting enclosure-level cooling for particular racks with an adaptive control system, as described herein.

Systems and methods may be directed toward one or more control applications that including adaptive learning, live process data collection, and controller adjustments to live process conditions. According to one embodiment, algorithmic controls respond to read and write processes from multiple ambient environment sensors, multiple hydronic system sensors, multiple internal environment sensors, as well mechanical sensors and safeties for a number of environments, and then stores and categorizes the stored data by continually comparing that data to live incoming new data. The control system may then adjust the input/output (I/O) process of a variety of different concurrently executing algorithmic computations by sending out calculated write request with overrides of how to achieve the most favorable method of control for each system. As a result, embodiments of the present disclosure may include a process to learn an optimal and economical strategy for all environments internal or external to a cabinet enclosure. In at least one embodiment, initial control strategies may use, as a baseline or starting point, manufacturer specified optimal parameters. However, as the system operates and collects control data, one or more learning techniques may be used to detect and implement enhancements to the initial control strategies, for example for a number of different control environments. Adjustments may be made to each system and sent out adaptively. As different adjustments are made to different systems, the entire system, as a whole, may run more efficiently and/or within parameters to improve life of various components. In operation, the control scheme discussed herein may implement one or more algorithms to respond and write to one or more active environment control methods from a learned process while a load is active. Systems and methods may also implement manual override changes to different algorithmic or automated controls. Accordingly, systems and methods of the present disclosure provide control for mission critical facilities, whether being a new deployment or a retrofitted deployment. Embodiments may include adaptive learning abilities to provide various advantages over existing systems and problem solutions to problems with whole-facility cooling, as discussed herein.

In operation, various embodiments may include one or more control units, such as a programmable logic controller (PLC) with internal storage, cache ability, programmable I/O and ANSI/ASHRAE standard that specifies a common communication protocol that allow building systems (e.g., systems associated with datacenters) to communicate with each other using a common language. The PLC may include three main types of recordable data contained within: “structured data” to identify one or more elements of the manufactures optimal perimeter specifications and logical data, which is split between various input and output, data strings, which envelopes the logic structure and mathematical calculations to achieve and compare the learned and adaptive data. Accordingly, as discussed herein, embodiments provide a mission critical logical algorithm with adaptive learning that will overcome shortcomings of the prior art and their methods of interpreting data and control. Additionally, at least one embodiment provides a platform for the algorithm interfacing it with interchangeable graphics that provide incrementally expandable and diverse storage of the learned data in logical form and how it can be utilized throughout various systems.

Systems and methods of the present disclosure may be directed toward an adaptive control system with integrated learning capabilities. In at least one embodiment, different sub-systems may be independently controlled based on one or more desired operational parameters. By way of example, a cooling load may be established by tonnage and then components of a cooling system, such as a valve position, an inlet cooling fluid temperature, etc., may be controlled to meet the desired operational parameters. Whole system control may then be regulated by combining and modifying different system and sub-system level control points. As one example, tonnage may be directly related to load within a cabinet enclosure because it may require less cooling capacity to cool a system with reduced load. As a result, the efficiency or cooling capacity may include, as one factor in determining how to regulate different components of the cooling system, the current or anticipated load for a given cabinet enclosure. In at least one embodiment, load may be correlated to one or more measurements, such as a temperature measurement obtained from one or more sensors within or associated with the cabinet enclosure. In this manner, a variety of different sensor data may be used to monitor and predict conditions to control operational aspects for one or more associated systems or sub-systems.

In at least one embodiment, systems and methods of the present disclosure may adaptively modify different operating conditions based on historical information that may be used to establish one or more set points or desired operating parameters. As one example, systems and methods may be used to identify one or more salient features or control points (e.g., internal temperature, tonnage, flow rate, etc.) and then, based on the value of the control points, may identify one or more corresponding operating parameters for different systems and sub-systems in order to replicate or achieve a “best” or “optimal” operation. For example, if an internal temperature is used as an example control point, systems and methods may be used to identify one or more historical sets of operating parameters associated with a similar internal temperature (e.g., within a threshold) and then may adjust one or more operating parameters to match or closely match the historical sets. Operation may then continue with the adjusted operating parameters and one or more metrics may be computed and compared to the associated metrics for the historical sets of operating parameters. If the metrics are worse than the historical metrics, then one or more additional adjustments may be performed. Thereafter, if the metrics exceed the historical metrics, then the historical metrics may be replaced with the current operating parameters being established as the new desired set of operating parameters. In this manner, individual components may be adjusted and the overall system, or sub-systems thereof, may be monitored and controlled for continuous improvement.

Various embodiments of the present disclosure may be executed as one or more sets of stored computer instructions using one or more processors. Embodiments may be used to overcome problems with existing systems that apply reactive operational changes based on sensor readings instead of anticipating upcoming changes based on monitoring different sensor readings and predicting future needs, for example by evaluating trends or comparing changes in information to historical data. Accordingly, systems and methods may be used to predict changes in operating conditions and adaptively adjust various components of a cooling system to proactively adapt to upcoming changes.

While various embodiments of the present disclosure may be directed toward cabinet enclosures and/or datacenter cooling applications, it should be appreciated that one or more embodiments may be used in a variety of industrial, commercial, and/or residential capacities with respect to monitor and control of different cooling applications. As a result, systems and methods may be directed toward improved efficiency, control, and effectiveness of a variety of different applications. By way of example, embodiments may be directed toward a variety of sensors arranged within a residential area to detect temperature, air flow, air pressure, hydronic pressure, and/or the like and then adjust different operating conditions for a variety of different connected components, such as air conditioning units, fans, heat generating units, louvers, and/or the like. In another example, such as an industrial application, embodiments may be used to efficiently control different areas or locations associated with storage or containment of various goods. As one example, a supermarket may include areas that have different temperature control parameters, such as perishable items compared to shelf stable items or a dairy section compared to a bulk good section. Embodiments of the present disclosure may be used to evaluate conditions at different locations within the store and then adjust different parameters of associated equipment in order to improve efficiencies. For example, fans and cooling units near the dairy may be operable in a different configure than fans and cooling units for the non-perishable goods due to their different intended operating conditions (e.g., preservation versus user comfort). Various embodiments may deploy cooling configurations to establish operating parameters, monitor trends and/or activities, and then adjust different operating conditions for future use and/or current use based on a most efficient or target efficient operation. Accordingly, cabinet enclosures and datacenters are provided as one non-limiting application for various systems and methods discussed herein.

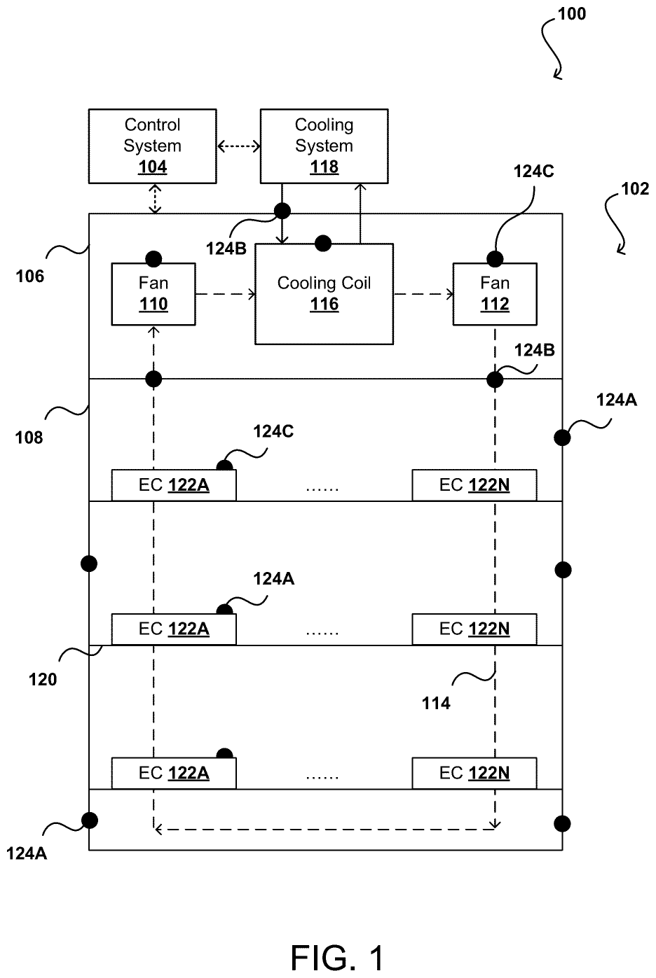

FIG. 1 illustrates an example environment 100 that may be used with embodiments of the present disclosure. This example includes a cabinet enclosure 102, which may also be referring to as a cooling cabinet, cabinet, and/or the like. The cabinet enclosure 102 may be arranged within a datacenter, for example among a variety of other cabinet enclosures (not pictured) and/or with traditional datacenter arrangements including hot/cold aisles, among other configurations. Accordingly, systems and methods may be directed toward a mobile, deployable, and separately controllable cabinet enclosure 102 that may use one or more control systems 104 to regulate operational parameters of the cabinet enclosure 102 and/or components thereof. In at least one embodiment, the cabinet enclosure 102 may correspond to one or more enclosures from DDC®, such as an S-Series or R-Series cabinet, among various other options. In at least one embodiment, the cabinet enclosure 102 may include one or more features associated with and/or described in U.S. patent application Ser. No. 17/652,323 or U.S. patent application Ser. No. 17/648,174, each of which are hereby incorporated by reference in their entireties for all purposes.

The illustrated cabinet enclosure 102 includes a cooling section 106 and a storage section 108, but it should be appreciated that these regions are described by way of non-limiting example only and are not intended to limit the scope of the present disclosure. The illustrated cooling section 106 includes a pair of fans 110, 112 in a push/pull configuration to direct a flow of air 114 over a cooling coil 116. In at least one embodiment, the push/pull configuration may refer to fan pairs having perpendicular axes (e.g., perpendicular axes of rotation for fan blades). The cooling coil 116 may receive cooling fluid, such as water, glycol, and/or the like, from a cooling system 118. As discussed herein, in at least one embodiment, the control system 104 may be used to regulate or otherwise control one or more operational parameters of the cabinet enclosure 102, which may include components of the fans 110, 112, cooling coil 116, cooling system 118, and/or the like. In at least one embodiment, the cooling system 118 may included one or more heat exchangers, pumps, valves, and/or the like to direct cooling fluid to the cooling coil 116. In operation, as the air 114 passes over/through the cooling coil 116, heat may be dissipated away from the air 114, which is then redirected through the storage section 108 to cool the components therein, as illustrated by the dashed arrow.

In this example, the storage section 108 includes a number of racks 120 that may be used to house, support, or otherwise store one or more electronic components 122, which may include components such as central processing units (CPUs), graphics processing units (GPUs), servers, memory units, switches, control systems, power supplies, and/or the like. The different electronic components 122 may generate heat during operation and the air 114 may be used to cool the electronic components 122 by directing the heated air from operation away in favor of the cooled air 114. In this manner, operation of the electronic components 122 may be maintained at one or more desired parameters, which may correspond to a temperature of the electronic components 122, an internal temperature of the storage section 108, a cooling capacity per load, a tonnage, a flow rate, and/or the like or combinations thereof.

Various embodiments may include one or more sensors 124 (represented by the circles) positioned within the cabinet enclosure 102 and/or associated with equipment supporting the cabinet enclosure 102. By way of non-limiting example, various sensors 124 such as temperature sensors, flow rate sensors, pressure sensors, humidity sensors, pH sensors, valve position sensors, load sensors, fan sensors, proximity sensors, and/or the like may be incorporated into the cabinet enclosure 102 and/or supporting equipment in order to monitor one or more parameters of the cabinet enclosure 102. In at least one example, temperature sensors 124A may be used at different locations within the cabinet enclosure 102 to measure temperature, for example at a top cabinet location and a bottom cabinet location, among others. Information acquired by the temperature sensors 124A may be used to determine (e.g., calculate, infer, etc.) temperature differentials and/or adjust one or more operating conditions. Temperature information may also be used for data visualization, such as to establish a temperature gradient and/or to illustrate and model air flow through the storage section 108. For example, if temperature were to increase in one area of the cabinet enclosure 102, a cooling fluid flow rate may be increased to the cooling coil 116, which would lead to cooler air 114, and therefore more cooling within the storage section 108. As another non-limiting example, one or more flow sensors 124B may be used to monitor air flow rates and/or cooling fluid rates. The air flow rates may be used to determine (e.g., calculate, infer, etc.) fan speeds or motor loads for the fans 110, 112. In at least one embodiment, cooling fluid flow rates may be used to determine (e.g., calculate, infer, etc.) pump operational parameters, valve position, flow line fouling, pressure differentials, and/or the like. Similarly, separate sensors may also be deployed for use with the motors associated with the fans 110, 112. In another example, sensors may be deployed to measure valve position with respect to the cooling system 118 and, based on one or more other parameters, valve position may be adjusted to increase or decrease cooling water flow to the cooling coil 116. Additionally, in at least one embodiment, load may be measured with respect to an energy draw for one or more components within the cabinet enclosure 102. By way of non-limiting example, one or more load sensors 124C may be used to determine a load drawn by the electronic components, a load drawn by the fans 110, 112, and/or the like. In this manner, different sensors 124 may be deployed to collect information associated with the internal environment of the cabinet enclosure 102 and/or with the supporting systems associated with the cabinet enclosure 102 and then that information may be used to adjust and regulate one or more different operating conditions in accordance with different control parameters discussed herein.

In at least one embodiment, sensor fusion may enable control of various operating parameters based on a multi-dimensional analysis of input information. For example, if temperature were found to be trending upwards, for example by monitoring temperature at a certain location over a period of time, it may be desirable to address the temperature increase in a number of different ways. For example, increasing cooling fluid flow to the cooling coil 116 may reduce a temperature of the air 114 as it enters the storage section 108, which may facilitate cooling. Additionally, increasing a fan speed to increase a volume of air flow may also increase cooling, but could also adversely affect cooling if too much air flow volume is increased. Accordingly, systems and methods of the present disclosure may evaluate different adjustments for a number of parameters to determine an efficient adjustment to maintain a set point, such as temperature. For example, it may be advantageous to both increase cooling fluid flow and increase fan speed, but to a lesser extent than doing only one or vice versa. Embodiments may provide a control system to analyze and evaluate different sensor data in order to adaptively control operating conditions. Thereafter, if a particular set of operating parameters is proven to be efficient, the set may be trapped and used as an initial starting point in future operations, with additional adjustments being made based, at least in part, on sensor data. For example, in at least one embodiment, parameters may be referred to as trapped because the set of operating parameters may not be non-volatile memory integers. While embodiments may be used to make each point a non-volatile integer, it should be appreciated that systems and methods of the disclosure may be used to either trap or store data associated with different operating parameters.

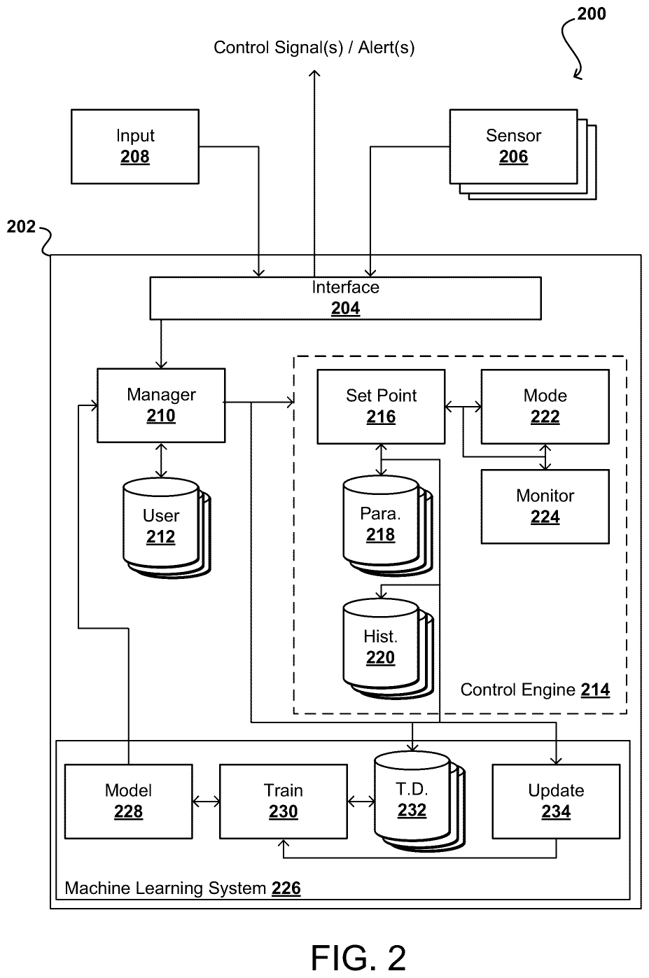

FIG. 2 illustrates an example environment 200 that may be used with embodiments of the present disclosure. In this example, the environment 200 corresponds to a control system 202, which may be associated with the control system 104. The control system 202 may receive one or more signals from a variety of different sources over one or more networks, which may be wired or wireless networks. In at least one embodiment, the control system 202 may operate separately from a network used to manage other operations within a datacenter. In other embodiments, the control system 202 may be integrated into overall management of the datacenter, for example, receiving information regarding upcoming loads to different servers/racks, receiving information regarding overall cooling/environmental information, and/or the like. In this manner, the control system 202 may be used to dynamically adjust and predictively change one or more operating parameters for a cabinet enclosure to accommodate overall operations within the datacenter.

An interface 204 receives information provided via one or more sensors 206 and/or an input 208, such as an input provided by a user or one or more user devices, such as a computer, smart phone, handheld device, server, and/or the like. The input 208 may be an input provided by the user or may be associated with a workflow triggered by one or more operations associated with a connected user device. For example, the input 208 may be responsive to a user providing an input to a device, but the input may include more information and/or commands than the input provided by the user. The interface 204 may include one or more entry points or application programming interfaces (APIs) and may be accessible over a network connection, such as the Internet. Accordingly, systems and methods may enable remote control and monitoring of the control system 202.

A control manager 210 (e.g., manager) may receive and route different input signals, such as sensor information and/or the input instructions. The manager 210 may also process and implement output signals, such as transmitting control signals and/or alerts responsive to determinations and/or operations of one or more control algorithms discussed herein. In this example, the manager 210 may acquire user settings from one or more user datastores 212 in order to provide instructions to a control engine 214 to determine and establish different operating conditions for a cabinet enclosure. By way of example, the user datastore 212 may include user preferences, such as desired thresholds (e.g., temperature, load, tonnage, flow rates, etc.), desired efficiency metrics, operating parameters, and/or the like. As a result, different operational parameters may be tuned based on different user settings/information. Furthermore, the user preferences may be for either a datacenter operator and/or for individual clients of the operator, such as particular clients executing operations using different computing devices. Accordingly, fine-tuned operational parameters may be established based on individual user settings.

The control engine 214 may include a variety of systems and/or sub-systems and may itself be further integrated into a different control configuration, and as a result, the illustrated embodiment showing different engines and components is by way of non-limiting example only. In at least one embodiment, the control engine 214 is used to execute one or more software systems that may include different algorithms executed by a process based on instructions stored in memory. In at least one embodiment, the control engine 214 may receive sensor information, for example from the sensors 206, as inputs to control one or more operating parameters of one or more cabinet enclosures. For example, systems and methods may be used for direct control over a single cabinet enclosure and/or portions thereof or systems associated with the cabinet enclosure, such as fans, cooling systems, and/or the like. Additionally, the control engine 214 may be used to control multiple different cabinet enclosures, for example to execute different operating parameters for total datacenter efficiency or operational control. By way of example, the datacenter operator may desire to reach certain energy consumption thresholds and/or cooling capacities, and as a result, different individual cooling enclosures may be controlled to meet or exceed a datacenter baseline.

In this example, a set point engine 216 is used to determine one or more operating conditions for one or more cabinet enclosures using at least input data, such as from the sensors 206, and or input instructions, such as from a user. For example, the set point engine 216 may determine one or more desired operating conditions for a cabinet enclosure and then adjust different individual settings to reach or exceed the desired operating conditions. By way of non-limiting example, if an internal temperature is the desired operating condition, then the set point engine 216 may use sensor information to determine an internal temperature (e.g., temperature at a given measuring location, a temperature gradient over an area, a differential between two temperature readings, etc.) and then adjust one or more operating conditions such that the internal temperature meets or exceeds a desired value. Different operating conditions could include increasing a fan speed, increasing a cooling water flow rate, increasing a time that cooling air is maintained within a cabinet (e.g., decreasing a pressure differential across the electronic components), and/or combinations thereof. Additionally, the set point engine 216 may also be used to determine whether one or more external factors may be adjusted to reach the set point, such as determining that a door to a cabinet enclosure is open or determining an upstream cooling fluid temperature is higher than a desired value. In this manner, the set point engine 216 may evaluate and adjust a variety of different parameters, which may be based on multi-dimension algorithms and/or sensor fusion, in order to establish different operating conditions.

In at least one embodiment, the set point engine 216 may receive information from a parameter datastore 218 and/or a historical datastore 220. The parameter datastore 218 may include different operating parameters for certain associated equipment, which may be based on equipment capabilities, operating preferences, and/or the like. For example, the parameter datastore 218 may include maximum operating parameters for certain equipment and use those values as thresholds or limits when establishing set points to maintain equipment integrity. Similarly, the parameter datastore 218 may be used to update different operating conditions over time based on equipment wear or useful life. For example, if a fan is determined to be out of balance, it may be desirable to run the fan at a lower speed until the unit can be taken offline for repairs. As another example, if a valve is set to undergo preventative maintenance, it may be desirable to provide an alert and notify the operator to switch or otherwise migrate operations for the entire cabinet enclosure in advance of the maintenance.

Furthermore, the setpoint engine 216 may also be used to determine current operating conditions against expected or known-flawed operating conditions. For example, one or more embodiments may use parameters of operating conditions to draw relationships between normal and abnormal operation of various components. As one non-limiting example, systems and methods of the present disclosure may be used with fan operational evaluation to make a determination or inference regarding a fan operating condition. For example, fan data may be used to determine whether or not a fan is running backward/reverse rotation or in a forward or desired rotation. In at least one embodiment, systems and methods may use sensor data to obtain information from one or more fans associated with a cold deck or a hot deck, as discussed herein. A relationship or other correlation between fan operation may be determined. For example, it may be determined that the cold deck fan should operate with higher or equal amps than the hot deck fan. If such a relationship is not maintained, it may be determined that the hot deck fan is running backwards. Various relationships of this manner may be inferred, for example using one or more machine learning systems discussed herein, and may be used to establish a variety of different alarm parameters, thereby providing improved monitoring of various cooling system.

The historical datastore 220 may maintain different operating parameters for the cabinet enclosure over time. For example, a “best” operating condition may be stored, marked, tracked, and then updated as different operations are performed. The “best” operating condition may be determined based on one or more desired or established metrics, such as power consumption, cooling water use, tonnage, temperature, and/or the like. In at least one embodiment, the historical datastore 220 may be used to predict or otherwise establish initial operating parameters when a new load or configuration is to be deployed with the cabinet. For example, the historical datastore 220 may include information such as a load drawn by the electronic equipment, fan speed, cooling water flow rate, and/or the like. If a new operating condition is expected or predicted, such as a lower load and/or a higher load, systems and methods may use the historical datastore 220 to identify a similar configuration (e.g., within a threshold amount) and then initially set operating parameters at that predicted level, monitor the operations over time, and then make adjustments in accordance with different sensor readings. For example, if a threshold internal temperature is desired and the operating parameters for the prediction provide cooling that exceeds the desired internal temperature, fan speed or cooling water flow rate may be reduced, thereby reducing energy use and potentially increasing efficiency. As another example, providing an initial or baseline configuration may reduce initial guess and check to determine or identify an operating condition, thereby reducing a time to get the cabinet enclosure to a desired operating level.

In at least one embodiment, a mode engine 222 may be used to provide information to the set point engine 216 to adjust different operational parameters. As one example, a mode of operation may include vortex mode in which it is determined that a cold deck for the enclosure includes a leak (e.g., due to being open). In this mode of operation, desired set points may be overridden based on different salient or operational information. For example, upon determining the cold deck door for the enclosure is open, the mode engine 222 may trigger vortex mode and then increase operating conditions for the fans to preemptively maintain cooling conditions. As another example, if it is determined that there is a fan failure, the mode engine 222 may trigger a mode to ramp up the remaining fan operating conditions to maintain cooling. Different modes may be preprogrammed or determined over time with different operating conditions and then be used to override or otherwise help establish different set points.

A condition monitor 224 may be used to evaluate different operating conditions to determine whether the historical datastore 220 is updated to establish a new “best” operating conditions, among other monitoring operations. For example, the condition monitor 224 may evaluate different parameters over time and then compute or otherwise determine an efficiency or other operating metric for different operating conditions. The condition monitor 224 may evaluate different operating parameters over time and then tag one or more salient features to determine whether to update a configuration. In at least one embodiment, a threshold period of time may need to be reached prior to updating, such as operating at a new high efficiency for longer than a period of time and/or continuously over some range. In this manner, updates and modifications may be based on maintainable operating parameters instead of short-term changes in state.

Systems and methods of the present disclosure may further deploy one or more machine learning systems 226, which may be incorporated into the control engine 214 in various embodiments. One or more models 228 may be used to compute one or more operating conditions based on a variety do different inputs. For example, the models 228 may be trained using a training engine 230 and training data from a training datastore 232 to establish the different set points used by the set point engine 216. The models 228 may develop multi-dimensional relationships between different operating conditions, such as load, fan speed, cooling fluid flow rates, pressure, and/or the like. Additionally, the one or more models 228 may be updated based on one or more update engines 234 that may evaluate different set point information and/or operating conditions and then trigger different training updates to the training engine 230. In at least one embodiment, models may be retrained or trained with targeted information on a regular basis, on the determination of a new set point, when new systems are deployed, and/or combinations thereof.

The models 228 may include a variety of different statistical machine learning techniques. In at least one embodiment, the models 228 may include different artificial neural networks or deep learning systems, which may include convolutional neural networks (CNNs), recurrent neural networks (RNNs), multilayer perceptrons (MLPs), and/or the like. Additionally, different training mechanisms, such as supervised training, unsupervised training, or hybrid training methods may be deployed. As one non-limiting example, a target set of operating conditions may be determined based on one or more input variables, such as tonnage, temperature, and/or the like. The network may then be trained on input data to determine a set of tunable parameters to achieve the target set of operating conditions. Over time, new information may be used to train and adjust different weights for the network, thereby enabling predictive output operating parameters based on different input variables. In this manner, embodiments may adapt and/or predict different operating conditions based on different input variables. The models 228 may also be used to predict upcoming maintenance or failures for different components. For example, reduced fan speeds when receiving the same load may be indicative of a failure. Accordingly, embodiments may deploy one or more models 228 to monitor system component health and then provide alerts or notifications regarding expected upcoming maintenance or operational upsets.

Embodiments of the present disclosure may be used to deploy one or more control systems for one or more cabinet enclosures, which may include individual cabinet-level control, multi-cabinet control, or datacenter-level control, and/or combinations thereof. Embodiments may include different sensor inputs that are received by one or more engines 214 to control and adjust different operating parameters for associated equipment with the cabinet enclosures. In at least one embodiment, historical information may be used to predictively select operating conditions based on expected or current load conditions for a cabinet enclosure, such as a load or temperature, among other options. Accordingly, systems and methods of the present disclosure may dynamically adjust operating conditions to respond to changes in the cabinet enclosure. Furthermore, one or more embodiments may be used to adaptively learn different operating parameters and then adjust future operating conditions in accordance with the learned information.

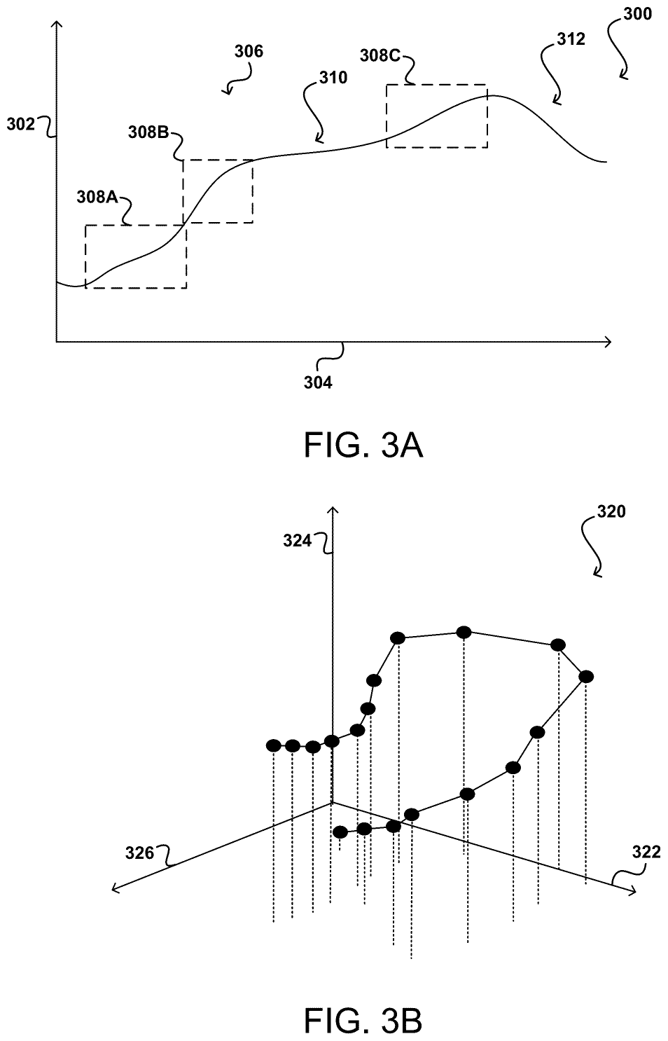

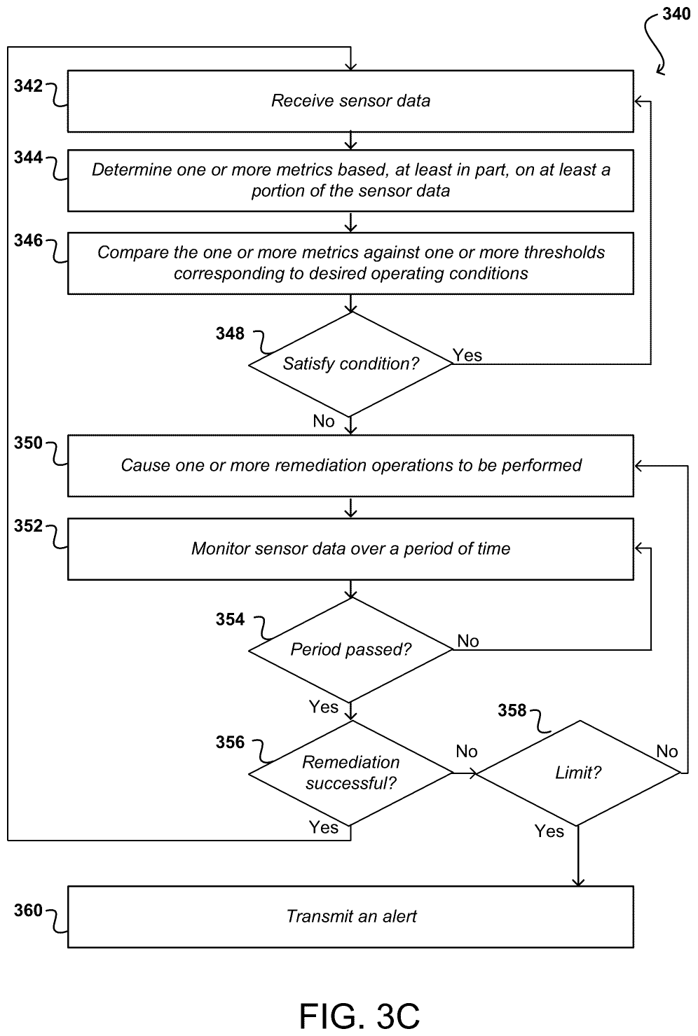

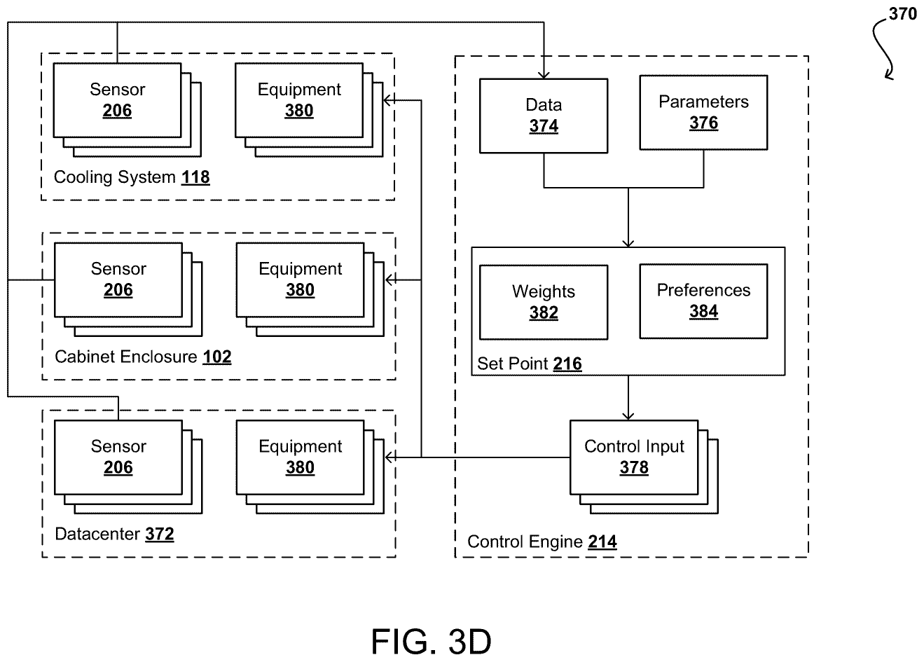

FIG. 3A illustrates a graphical representation of a plot 300 that may correspond to an evaluation of one or more parameters that are measured for a cabinet enclosure. In this non-limiting example, the y-axis 302 may correspond to temperature and the x-axis 304 may correspond to time. As a result, a rate of rise may be determined, which may be used as one threshold or trigger value to adjust one or more operational parameters of the cabinet enclosure.

In at least one embodiment, the rate of rise may refer to a slope of a trendline associated with different temperature readings at different times. The trendline may be developed over sensor data 306 that is received and plotted over some period of time. In other words, the rate of rise may refer to an amount of increase of one value (e.g., temperature) over a specified period of time. In at least one embodiment, different bins 308 may correspond to different periods of time for computing a rate of rise. By way of non-limiting example, an increase of approximately 1 degree C. over 5 minutes may be considered a threshold level of rise, and as a result, may trigger one or more follow on actions, such as an increase in cooling water flow rate, increased fan speed, and/or the like. Various embodiments may enable tuning one or more hyperparameters associated with the bin 308, such as changing a duration of time for computation of the rate of rise. Different rates of rise, or various other threshold parameters, may be stored, monitored, and updated based on different sensor readings and/or associated operations of the cooling enclosure. Moreover, values may change over time. For example, after a maintenance operation the rate of rise may be different than a cooling cabinet that is closer to a scheduled maintenance operation, thereby reflecting reduced efficiencies or ability to recover associated with the supporting equipment. In this manner, different threshold values may be dynamically adjusted over time, for exampling using one or more machine learning systems, historical data, and/or combinations thereof.

In this example, a first bin 308A corresponds a region with a first rate of rise, a second bin 308B corresponds to a region with a second rate of rise, and a third bin 308C correspond to a region with a third rate of rise. As discussed, this example may refer to a rate of rise as a slope for a given bin 308, but other values and/or determinations may also be used with embodiments of the present disclosure. For example, rather than looking at rate of rise, a duration of rise may be evaluated, for example determining that temperature is rising for a threshold duration of time. As another example, load may be evaluated to determine whether load is changing over different periods of time. Accordingly, systems and methods may implement a variety of different operational determinations to draw correlations between different positions/operations and desired cooling levels.

Various embodiments may be used to establish a different threshold condition for a given operational time, such as rate of rise over a given bin 308. In the example of FIG. 3A, the rate of rise over the bin 308A may not exceed a threshold, and as a result, no remediation operations may be executed, such as adding cooling capacity to the cabinet enclosure. However, the rate of rise for bin 308B may exceed a threshold, and as a result, one or more remediation actions may be triggered, as illustrated by the decreased rate of rise in the region 310. As the bin 308C is evaluated, it may be determined that the threshold is exceeded again, which may cause one or more additional remediation operations, which may be shown to be successful in the region 312 due to the decrease in temperature. Various embodiments may deploy such evaluation techniques to evaluate, remediate, verify remediation success, and then continue to monitor operations in order to establish different operating parameters in line with one or more desired operating conditions.

FIG. 3B illustrates a graphical representation of a plot 320 that may correspond to an evaluation of one or more parameters that are measured for a cabinet enclosure. In this non-limiting example, the y-axis 322 may correspond to a first measured value (e.g., temperature), the x-axis 324 may corresponds to a second measured value (e.g., flow rate), and the z-axis 326 may corresponds to a third measured value (e.g., fan speed). Accordingly, a multi-dimensional analysis of the cooling cabinet may be performed by correlating how different operating parameters may affect or otherwise change others. It should be appreciated that multiple multi-dimension analyses may also be combined, for example by generating a value associated with a given value, in order to combine a variety of different information types into a single measure of operational efficiency associated with the cooling enclosure.

FIG. 3C illustrates an example process 340 for monitoring operational parameters of a cooling enclosure in accordance with various embodiments. It should be understood that there can be additional, fewer, or alternative steps performed in similar or alternative orders, or in parallel, within the scope of the various embodiments unless otherwise specifically stated. In this example, sensor data is received 342. The sensor data may come from a variety of sources and may monitor a variety of different parameters for a cooling enclosure, as discussed herein. The sensor data may be received at set intervals or may be received upon demand, such as when a request is transmitted to pull sensor information. It should be appreciated that different sensor data may be received at different times in accordance with one or more preferences established by an operator. For example, some data may be more costly to acquire continuously, and as a result, may be acquired at different intervals. Similarly, some data may be acquired such that too much data is presented, and therefore, data may be normalized or aggregated over periods of time. The data may also be processed data, such as data that has been converted using one or more algorithms.

In this example, one or more metrics are determined for at least a portion of the sensor data 344. The metrics may be associated with different desired parameters or monitored conditions, such as a temperature gradient over a height of an enclosure, a flow rate at different locations, a cooling fluid flow rate, and/or the like. The one or more metrics may be compared to one or more thresholds 346, which as discussed herein may be adaptively changed and/or adjusted based on different operating conditions. For example, a threshold may be replaced with a new threshold corresponding to a more efficient operating configuration. It may be determined whether or not the current one or more metrics fails to satisfy a threshold condition, such as exceeding a threshold, being below a threshold, being outside a range, and/or combinations thereof 348. If the condition is satisfied, sensor data may continue to be monitored over time.

If it is determined that one or more metrics does not satisfy the condition, then one or more remediation operations may be performed 350. For example, cooling fluid flow rate may be increased to reduce a temperature that exceeds a threshold. As another example, fan speed may be increased to raise cooling capacity. The changes may be gradual changes or may be executed over time, such as permitting a ramp up or ramp down period. Furthermore, changes may not all be associated with increases. For example, cooling fluid flow rate may be decreased if it is determined a temperature is less than a threshold, which may increase cooling efficiencies by reducing consumption of cooling fluid, lowering pump speed, and/or the like.

Sensor data may be monitored after the remediation action for a period of time 352 and, if the period of time passes 354, it may be determined whether or not the remediation was successful 356. If so, then the sensor data may continue to be monitored for any other changes. If not, then it may be determined whether a limit for remediation actions has been reached 358. If not, then another remediation action, which may be different, may be executed. If so, then an alert may be transmitted 360, such as an alert to schedule a maintenance operation for the cooling enclosure. In this manner, systems and methods may monitor a variety of different operational parameters of the cooling enclosure and then execute different remediation operations to adapt to changing conditions.

FIG. 3D illustrates a schematic representation 370 of an embodiment of a control scheme that may be used with embodiments of the present disclosure. In this example, different sets of sensor data 206 may be acquired from the cooling system 118, the cabinet enclosure 102, a datacenter 372, or any other reasonable location. It should be appreciated that additional systems and sub-systems may provide sensor or other information to the control engine 214. In this example, data 374 may be aggregated or otherwise prepared for combination with one or more parameters 376, for example from the parameter datastore 218, to evaluation by the set point engine 216. In this example, the data 374 may be a curated set of data, for example identifying particular datapoints for use and/or pre-processing the data, such as to remove noise. In at least one embodiment, the data selected may be based on different aspects of the control system, among various other options. The data 372 and parameters 376, among other information, may be used by the set point 216 to generate one or more control input 378 that may be used to control equipment 380 associated with the cooling system 118, the cabinet enclosure 102, the datacenter 372, and/or any other related equipment associated with the cabinet enclosure and/or that may affect cabinet cooling. In this example, weights 382 and/or preferences 384 may be applied to the data 374 and/or the parameters 376. By way of example, based on a desired cooling scheme (e.g., by tonnage, by temperature, etc.), different sensor information may be weighted differently and/or discarded. Similarly, different parameters 376 may be weighted differently based on desired requirements for a user and/or equipment capabilities. For example, it may be determined that a fan may be running near its maximum capacity, and as a result, set points 216 associated with increasing fan speed may receive a lower weight because increasing the fan speed may lead to other problems. Accordingly, systems and methods may evaluate and weigh multiple different data inputs when generating different control inputs 378 to regulate operation of the equipment 380 associated with cooling operations.

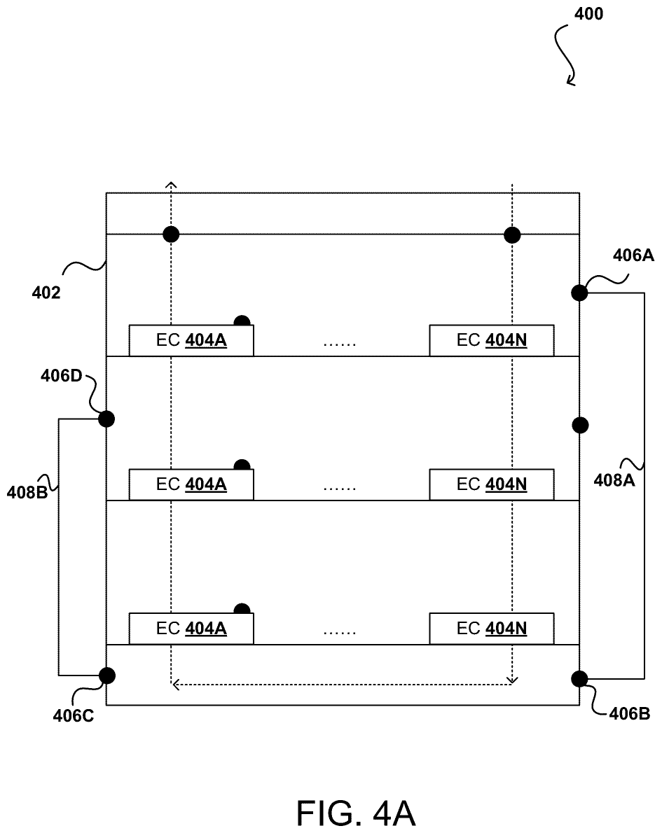

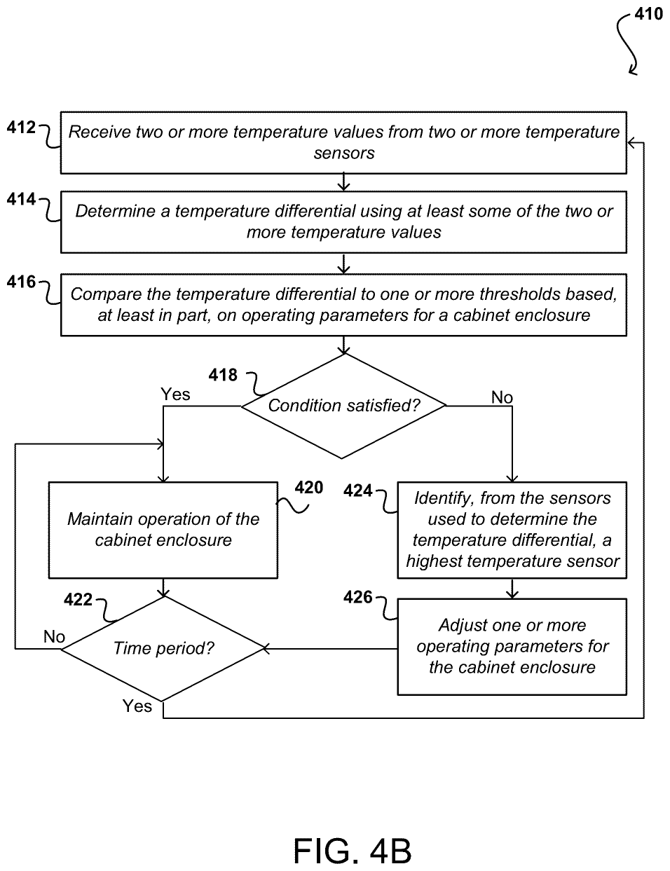

FIG. 4A illustrates a schematic diagram of an embodiment of an evaluation system 400 including a cabinet enclosure 402 housing a plurality of electronic components 404. As discussed herein, various features of the cabinet enclosure 402 may be shared with those associated with FIG. 1. In this example, a number of sensors 406 are arranged at different locations within the cabinet enclosure 402. The sensors 406 may include temperature sensors for this example, but it should be appreciated that a variety of other sensors may be incorporated into the cabinet enclosure 402, including pressure sensors, flow sensors, proximity sensors, humidity sensors, and/or the like. The illustrated embodiment may use temperature differentials to determine temperatures at different locations within the cabinet enclosure 402 and then control or otherwise regulate the temperature within the cabinet enclosure 402 based on a selected sensor 406, such as a sensor with the highest reading.

The sensor 406A is positioned at a top or upper location associated with the cabinet enclosure 402. In this example, the sensor 406A is proximate an inlet location for a cooling air flow, and as a result, the air flow may affect a reading provided by the sensor. Systems and methods of the present disclosure may address such a consideration by using additional temperature readings to control different operating parameters. A sensor second 406B may be positioned proximate a bottom or lower location of the cabinet enclosure 402 and a differential 408A between the two may be determined, which may be a computed differential taking a difference between measurements associated with the sensors 406A, 406B. The differential may then be evaluated against one or more thresholds, and if determined to be great enough, may cause one or more control operations to execute. For example, a differential value exceeding a threshold may cause a control operation to execute to control based on the highest temperature value. However, as discussed herein, the temperature at the sensor 406A may be artificially low due to the incoming air flow. Accordingly, systems and methods may look at a number of different sensors and/or a number of different differentials.

By way of example, the sensors 406C, 406D may be evaluated and the differential 408B may be used to control operations of the cooling cabinet. As will be appreciated, cooling capacity of the air flow may be lost by the time the sensor 406D is reached, thereby potentially providing a more accurate representation of the temperature within the cabinet enclosure 402. Additionally, one or more embodiments may be used to determine a temperature differential or gradient across different areas of the cabinet enclosure 402, and thereafter may be used to control operations so that hot spots or high temperatures are effectively managed. In this manner, identifying the hottest areas for control may effectively identify the most salient values for control because it may be inferred that if the hottest area is controlled to be under a threshold, then the remaining cooler areas will also benefit from the cooling and remain under the threshold.

FIG. 4B illustrates an example process 410 for monitoring and regulating one or more cabinet enclosure parameters using a temperature differential. In this example, two or more temperature values are received 412. The temperature values may be obtained from temperature probes or other temperature acquiring devices, which may be positioned at different locations within the cabinet enclosure. In at least one embodiment, the temperature sensors are arranged at locations with an axial displacement, such as a top and/or a bottom of an enclosure. In another embodiment, the temperature sensors are located at different inlet or outlet positions to measure a temperature differential after cooling electronic components, after passing through a cooling coil, and/or combinations thereof. It should be appreciated that multiple different sensors may be used to acquire data and an average or gradient may be used as temperature values.

A temperature differential may be determined 414. The temperature differential may be selectively computed between selected temperature sensors, for example, at specific locations. The locations may vary based on operating conditions, load, enclosure size, and/or the like. The computer temperature differential may be compared to one or more thresholds, which may be selected based on operating conditions of the cabinet enclosure 416. For example, thresholds may be different based on desired cooling capacities or internal temperature preferences for a given enclosure. As another example, differentials may be different based on a number of type of electronic equipment within the enclosure.

A condition may be evaluated in view of the comparison 418. For example, a threshold may be evaluated to determine whether a differential meets or exceeds a value, is less than a value, is within a range, or combinations thereof. If the condition is satisfied, then the cabinet enclosure may maintain current operations 420 and, after a period of time has passed 422, additional temperature values may be received to continue to monitor and control the temperature enclosure. However, in at least one embodiment, it may be determined that the condition is not satisfied, such as the differential exceeding a value, and then a highest temperature sensor from the temperatures used to compute the differential may be identified 424. The highest temperature sensor may then be used to adjust one or more operating parameters of the cabinet enclosure 426. The process may then be repeated to monitor one or more differentials using the newly established operating parameters, thereby providing dynamic adjustment of the cabinet enclosure.

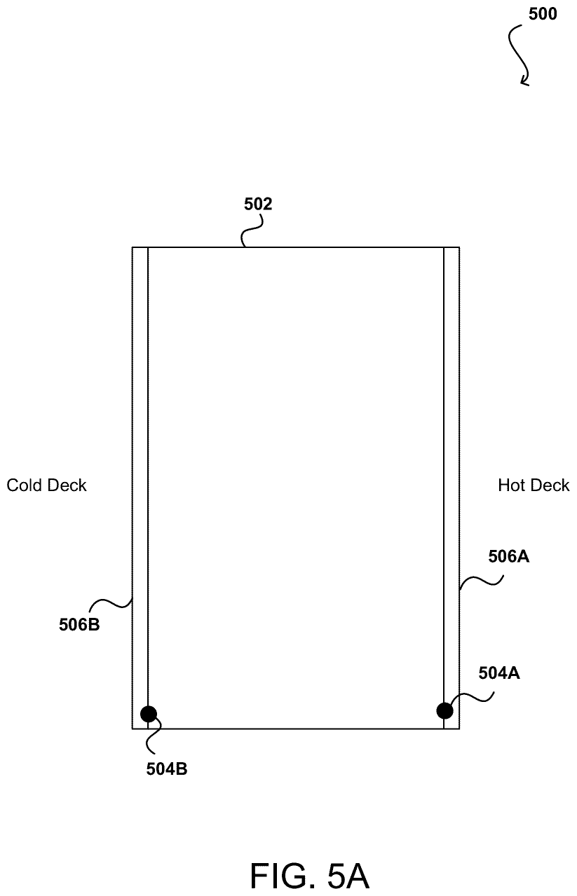

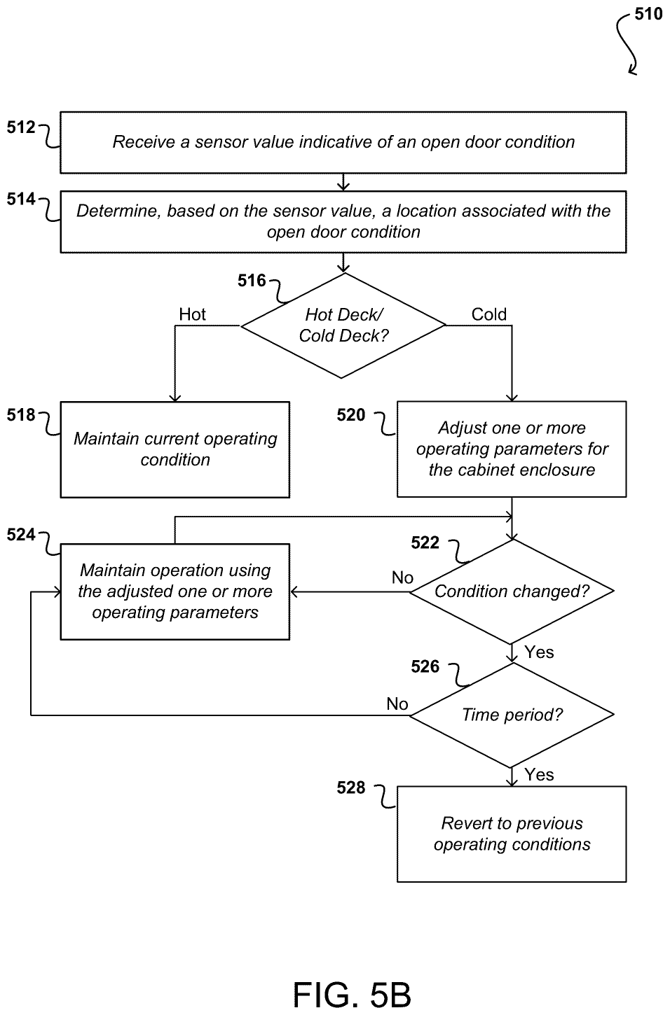

FIG. 5A illustrates a schematic diagram of an embodiment of an evaluation system 500 including a cabinet enclosure 502 housing a plurality of electronic components. As discussed herein, various features of the cabinet enclosure 502 may be shared with those associated with FIG. 1. In this example, proximity sensors 504A, 504B are arranged proximate to doors 506 associated with a hot deck and a cold deck of the cabinet enclosure 502. In operation, the cold deck may refer to a cold side associated with cooling air while a hot deck may refer to a hot side associated with air that has been used to cool electronic components.

The proximity sensors 504A, 504B may be used to determine whether or not the doors 506A, 506B have moved such that the doors 506A, 506B would be considered to be in an “open” position indicative of air loss. For example, if the door 506B is open, then cooling air will leak from the cabinet enclosure, thereby reducing cooling capacity. Systems and methods may be used to both identify and alert to open doors and also modify operations while doors are open to maintain cooling capacity.

FIG. 5B illustrates an example process 510 for monitoring and regulating one or more cabinet enclosure parameters using an indication of door proximity. In this example, a sensor value is received indicative of an open door condition 512. For example, one or more proximity sensors may provide a reading indicative of an open door. In at least one embodiment, a location or particular door associated with the open door condition may be determined 514. For example, in the non-limiting example of a cabinet enclosure, there may be multiple doors in different locations. As one example, there may be a first door associated with a hot deck and a second door associated with a cold deck. The identification of the door itself, and not only the condition of an open door, may be used to determine one or more continued operating parameters, as discussed herein.

In at least one embodiment, the sensor value and/or location may be used to determine whether the door open condition is associated with a hot deck or a cold deck 516. If the door open condition is associated with the hot deck, then current operating conditions may be maintained 518. However, if the open door condition is associated with the cold deck, one or more operating parameters for the cabinet enclosure may be adjusted 520. A vortex mode, as one non-limiting example, may be selected to ramp up fan speed in order to maintain cooling capacity while the open door is addressed. The condition that triggered the change in operating mode may continue to be monitored and it may be evaluated whether or not the condition has changed 522. Additionally, in certain embodiments, one or more alarms may be provided so provide an operator with information to address the problem. It should be appreciated that the alarm may provide information regarding the open door condition, a location of the associated enclosure, and/or an indication or reminder for the operator to use the proper personal protection equipment, such as hearing protection equipment. If the condition has not changed (e.g., if the door for the cold deck remains open), operation using the adjusted one or more parameters may be maintained 524. In at least one embodiment, the adjusted one or more parameters may be the continued mode of operation until it is determined that the condition has changed. For example, sensor information may be collected over one or more periods of time to evaluate the condition of the door. If the condition has changed, then a period of time may be evaluated to determine whether sufficient threshold duration has passed 526. The period of time may be an adjustable parameter. In at least one example, the period of time may be used to establish an equilibrium or trend toward a desired operating condition. After the period of time has passed, the cabinet enclosure may revert back to the previous operating conditions prior to the change 528. In this manner, a temporary adjustment may be provided while one or more detected conditions are addressed and corrected.

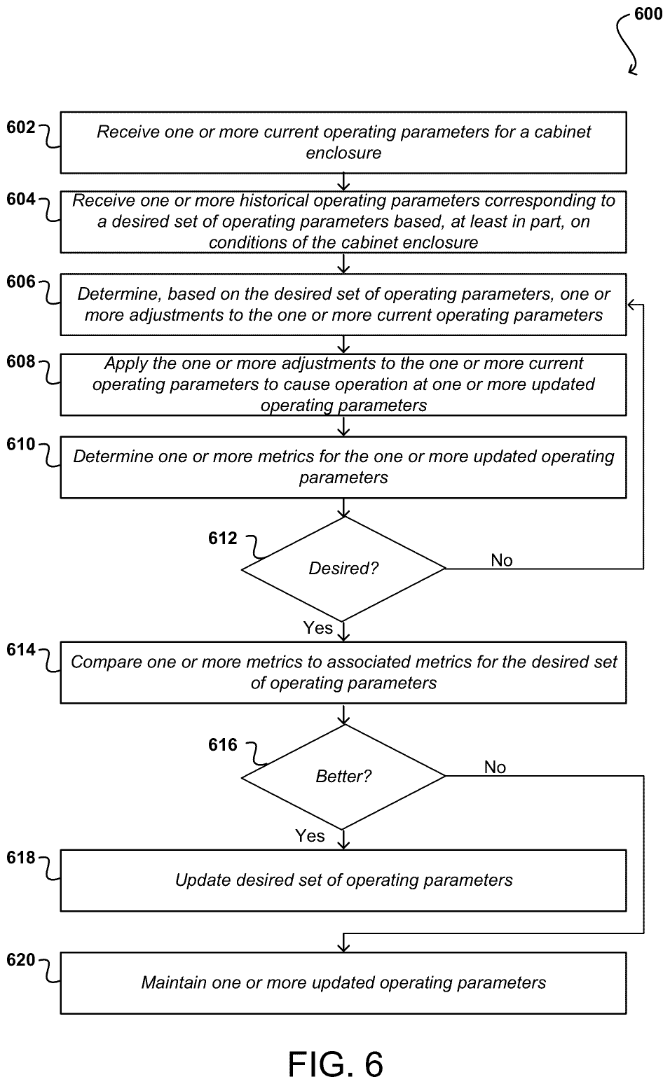

FIG. 6 illustrates an example process 600 for monitoring and regulating one or more cabinet enclosure parameters using historical operating conditions. In this example, one or more current operating parameters for a cabinet enclosure are received 602. For example, a set of operating parameters may be received, which my include different parameters for different components. In at least one embodiment, the set is provided by sensor data and/or parameters that are input by one or more operators. Historical operating parameters may be stored within one or more datastores. For example, operating parameters may be stored along with different conditions and/or specifications, such as operating parameters for different equipment at desired or set temperature differentials, load requirements, cooling capacity, and/or the like. Accordingly, the historical operating parameters may provide information for different operating conditions to meet one or more desired outputs or constraints.

In this example, historical operating parameters are received 604, and from these parameters, a desired set of operating parameters may be obtained. For example, the historical operating parameters may include a variety of different parameters for different conditions, but based on the current parameters, a particular set may be selected. By way of example, operating parameters may be different when efficiency is prioritized over cooling capacity. As another example, control based on temperature may be different from control based on cooling air flow rate. Accordingly, systems and methods may be used to evaluate different operating parameters from the historical information to identify the desired set of operating parameters.

The desired set of operating parameters may be used to determine one or more adjustments to the one or more current operating parameters 606. For example, it may be determined that different parameters may be adjusted to increase efficiencies or provide greater cooling capacity. As a result, historical data may be used to tune or otherwise adjust current operating parameters in an attempt to meet or exceed conditions that were previously achievable using the cabinet enclosure. The one or more adjustments may be applied 608 to cause the cooling cabinet to operate using one or more updated operating parameters.

After operating using the updated operating parameters, one or more metrics may be determined 610. The metrics may be associated with desired operating parameters/conditions of the cabinet enclosure, such as preferentially operating for temperature or efficiency, among other options. Additionally, metrics may be ranked and/or weighted to provide an overall metric score. For example, a cooling metric may receive a weight, a temperature metric may receive a weight, an efficiency metric may receive a weight, and so forth until an overall metric is computed. In this example, it may be determined whether or not the one or more metrics fall within desired specifications 612. For example, the desired specifications may refer to upper or lower thresholds, ranges, and/or the combinations thereof. If not, then new adjustments may be determined and applied. If so, then the one or more metrics may be compared to associated metrics for the desired set of operating parameters used to make the adjustments 614. The comparison may enable a determination for whether or not the updated operating parameters provided for an improvement over the desired set of operating parameters 616. If the updated operating parameters are better than the desired set of operating parameters, for example as determined by the metric comparison, then the updated desired set of parameters and historical operating parameters may be updated to include the updated operating parameters 618. If not, the cabinet enclosure may continue to operate using the parameters 620 or may optionally continue making adjustments. In this manner, operating parameters can be dynamically adjusted and new desired set points can be computed and updated for future improvements.

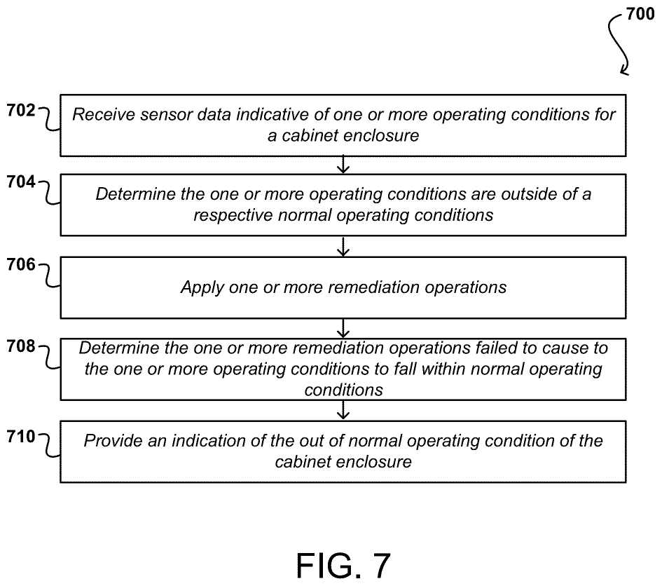

FIG. 7 illustrates an example process 700 for monitoring and regulating one or more cabinet enclosure parameters. In this example, sensor data indicative of one or more operating conditions for a cabinet enclosure is received 702. The data may be associated with a variety of information for cabinet equipment and/or support equipment, including, but not limited to, temperature information, cooling water flow rate, cooling water temperature, fan speed, fan flow rate, load, and/or the like. It may be determined that the one or more operating conditions are outside of a respective normal operating condition. For example, fan speed may be high or fan vibration may be high. Even if other parameters are within range, one or more abnormal operating conditions may be indicative of an upcoming failure event. As a result, systems and methods may be used to predict failure to schedule maintenance instead of reacting to failures.

In this example, one or more remediation operations may be applied 706. For example, if a valve position is shown as being abnormal the valve may be cycled or a controller may be reset. It may be determined that the one or more remediation operations have failed 708, and as a result, an indication for the out of normal operating condition may be provided 710. The indication may include an alarm or an indication to schedule maintenance, among various other options.

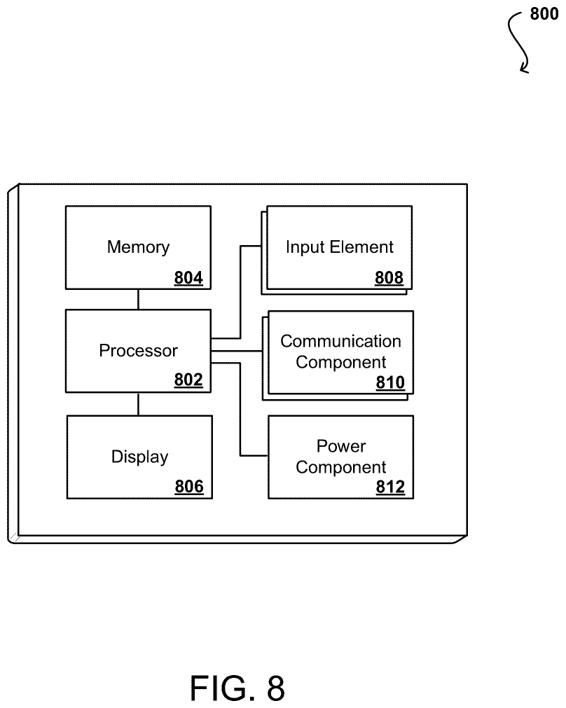

FIG. 8 illustrates a logical arrangement of a set of general components of an example computing device 800. In this example, the device includes a processor 802 for executing instructions that can be stored in a memory device or element 804. The device can include many types of memory, data storage, or non-transitory computer-readable storage media, such as a first data storage for program instructions for execution by the processor 802, a separate storage for images or data, a removable memory for sharing information with other devices, etc. The device may include a display element 806, such as a touch screen or liquid crystal display (LCD), although devices might convey information via other means, such as through audio speakers. As discussed, the device in many embodiments includes at least one input element 808 able to receive input from a user. This input can include, for example, a push button, touch pad, touch screen, wheel, joystick, keyboard, mouse, keypad, or any other such device or element whereby a user can input a command to the device. In some embodiments, the device might not include any buttons at all, and might be controlled only through a combination of visual and audio commands, such that a user can control the device without having to be in contact with the device. In some embodiments, the computing device 800 of FIG. 8 can include one or more network interface or communication elements or components 810 for communicating over various networks, such as a Wi-Fi, Bluetooth, RF, wired, or wireless communication systems. The device in many embodiments can communicate with a network, such as the Internet, and may be able to communicate with other such devices. The device also includes one or more power components 812, such as power cords, power ports, batteries, wirelessly powered or rechargeable receivers, and the like.

Example client devices used to interact with various embodiments can include any appropriate device operable to send and receive requests, messages, or information over an appropriate network and convey information back to a user of the device. Examples of such client devices include personal computers, smart phones, handheld messaging devices, laptop computers, set-top boxes, personal data assistants, electronic book readers, and the like. The network can include any appropriate network, including an intranet, the Internet, a cellular network, a local area network, or any other such network or combination thereof. Components used for such a system can depend at least in part upon the type of network and/or environment selected. Protocols and components for communicating via such a network are well known and will not be discussed herein in detail. Communication over the network can be enabled by wired or wireless connections, and combinations thereof.

It should be understood that there can be several application servers, layers, or other elements, processes, or components, which may be chained or otherwise configured, which can interact to perform tasks as discussed and suggested herein. As used herein the term “data store” or “datastore” refers to any device or combination of devices capable of storing, accessing, and retrieving data, which may include any combination and number of data servers, databases, data storage devices, and data storage media, in any standard, distributed, or clustered environment. A data store can include several separate data tables, databases, or other data storage mechanisms and media for storing data relating to a particular aspect. The data store is operable, through logic associated therewith, to receive instructions from a server, and obtain, update, or otherwise process data in response thereto.

Servers or other electronic devices may include an operating system that provides executable program instructions for the general administration and operation of that server or electronic device, and may also include a non-transitory computer-readable medium storing instructions that, when executed by a processor of the server or electronic device, allow the server or electronic device to perform its intended functions. Various embodiments or environments discussed herein may be facilitated or deployed as a distributed computing environment utilizing several computer systems and components that are interconnected via communication links, using one or more computer networks or direct connections. However, such a system could operate equally well in a system having fewer or a greater number of components than are described. Thus, the depictions of various systems and services herein should be taken as being illustrative in nature, and not limiting to the scope of the disclosure.

The environment can include a variety of data stores and other memory and storage media as discussed above. These can reside in a variety of locations, such as on a storage medium local to (and/or resident in) one or more of the computers or remote from any or all of the computers across the network. In a particular set of embodiments, the information may reside in a storage-area network (“SAN”) familiar to those skilled in the art. Similarly, any necessary files for performing the functions attributed to the computers, servers, or other network devices may be stored locally and/or remotely, as appropriate. Where a system includes computerized devices, each such device can include hardware elements that may be electrically coupled via a bus, the elements including, for example, at least one central processing unit (CPU), at least one input device (e.g., a mouse, keyboard, controller, touch screen, or keypad), and at least one output device (e.g., a display device, printer, or speaker). Such a system may also include one or more storage devices, such as disk drives, optical storage devices, and solid-state storage devices such as random access memory (“RAM”) or read-only memory (“ROM”), as well as removable media devices, memory cards, flash cards, etc.

Storage media and other non-transitory computer readable media for containing code, or portions of code, can include any appropriate media known or used in the art, including storage media and communication media, such as but not limited to volatile and non-volatile, removable and non-removable media implemented in any method or technology for storage of information such as computer readable instructions, data structures, program modules, or other data, including RAM, ROM, EEPROM, flash memory or other memory technology, CD-ROM, digital versatile disk (DVD) or other optical storage, magnetic cassettes, magnetic tape, magnetic disk storage or other magnetic storage devices, or any other medium which can be used to store the desired information and which can be accessed by the a system device. Based on the disclosure and teachings provided herein, a person of ordinary skill in the art will appreciate other ways and/or methods to implement the various embodiments.

Embodiments may also be described in view of the following clauses:

1. A computer-implemented method, comprising:
receiving one or more current operating parameters for a cabinet enclosure associated with cooling one or more electronic components;
receiving one or more historical operating parameters corresponding to a desired set of operating parameters based, at least in part, on one or more current conditions of the cabinet enclosure;
determining, based on the desired set of operating parameters, one or more adjustments to the one or more current operating parameters;
applying the one or more adjustments to the one or more current operating papers to cause operation of the cabinet enclosure at one or more updated operating parameters;
determining, for the one or more updated operating parameters, one or more metrics;
comparing the one or more metrics to one or more associated metrics for the desired set of operating parameters;
determining at least one metric of the one or more metrics exceeds at least one associated metric of the one or more associated metrics; and
updating a corresponding operating parameter for the at least one associated metric to correspond to an updated operating parameter corresponding to the at least one metric.

2. The computer-implemented method of clause 1, further comprising:
determining at least a second metric of the one or more metrics is less than a second associated metric of the one or more associated metrics; and
adjusting a second operating parameter associated with the second metric.

3. The computer-implemented method of clause 1, wherein the one or more current conditions correspond to at least one of a desired temperature, a desired air flow rate, a desired cooling capacity, or a desired load.

4. The computer-implemented method of clause 1, wherein the one or more operating parameters correspond to at least one of a cooling fluid flow rate, a valve position, a fan speed, or a differential temperature.

5. The computer-implemented method of clause 1, further comprising:
receiving one or more sensor readers corresponding to the one or more operating conditions.

6. A computer-implemented method, comprising:
receiving sensor data corresponding to a control parameter for a cabinet enclosure;
determining one or more metrics based, at least in part, on at least a portion of the sensor data;
comparing the one or more metrics to one or more threshold operating parameters;
determining the one or more metrics fail to satisfy one or more conditions of the one or more threshold operating parameters;
causing a change in one or more current operating settings associated with the control parameter for the cabinet enclosure;
determining, following a period of time after the change, one or more updated metrics based, at least in part, on at least an updated portion of updated sensor data;
determining the one or more updated metrics satisfy the one or more conditions for the one or more threshold operating parameters; and
causing operation of the cabinet enclosure in accordance with the one or more operating settings including the change.

7. The computer-implemented method of clause 6, wherein the control parameter is at least one of a desired temperature, a desired air flow rate, a desired cooling capacity, or a desired load.

8. The computer-implemented method of clause 6, further comprising:
determining, following a second period of time after the change, one or more second updated metrics based, at least in part, on at least a second updated portion of updated sensor data;
determining the one or more second updated metrics fail to satisfy the one or more conditions for the one or more threshold operating parameters;
determining a remediation limit has been reached; and
providing an alert regarding one or more components associated with the one or more operating settings.

9. The computer-implemented method of clause 8, wherein the alert is at least one of an auditory alarm or a visual alarm.

10. The computer-implemented method of clause 6, further comprising:
receiving second sensor data corresponding to a condition sensor;
determining, based on the second sensor data, an operating mode for the cabinet enclosure;
overriding one or more current operating conditions based on the operating mode; and
causing the cabinet enclosure to operate according to the operating mode.

11. The computer-implemented method of clause 10, wherein the condition sensor is a proximity sensor and the one or more current operating conditions includes increasing at least one fan speed.

12. The computer-implemented method of clause 10, wherein the condition sensor is a fan speed sensor, the operating mode is a first fan failure, and the one or more current operating conditions includes increasing a second fan speed.

13. The computer-implemented method of clause 6, further comprising:
receiving a plurality of sensor data over a period of time for a plurality of different associated cabinet components;
training one or more machine learning systems based, at least in part, on the plurality of sensor data; and
inferring, based on an input salient operating parameter using the trained one or more machine learning systems, one or more suggested operating parameters for the cabinet enclosure.

14. The computer-implemented method of clause 6, further comprising:
selecting an initial operating condition, for the cabinet enclosure, based on a salient operating parameter and one or more historical operating parameters;
comparing the initial operating condition to a current operating condition corresponding to operations using the one or more operating settings including the change;
determining the current operating condition has a higher performance than the initial operating condition; and
replacing the initial operating condition with the current operating condition.

15. A system, comprising:
at least one processor; and
memory including instructions that, when executed by the at least one processor, cause the system to:
   receive sensor data corresponding to a control parameter for a cabinet enclosure;
   determine one or more metrics based, at least in part, on at least a portion of the sensor data;
   compare the one or more metrics to one or more threshold operating parameters;
   determine the one or more metrics fail to satisfy one or more conditions of the one or more threshold operating parameters;
   cause a change in one or more current operating settings associated with the control parameter for the cabinet enclosure;
   determine, following a period of time after the change, one or more updated metrics based, at least in part, on at least an updated portion of updated sensor data;
   determine the one or more updated metrics satisfy the one or more conditions for the one or more threshold operating parameters; and
   cause operation of the cabinet enclosure in accordance with the one or more operating settings including the change.

16. The system of clause 15, wherein the control parameter is at least one of a desired temperature, a desired air flow rate, a desired cooling capacity, or a desired load.

17. The system of clause 15, wherein the instructions when executed further cause the system to:
receive second sensor data corresponding to a condition sensor;
determine, based on the second sensor data, an operating mode for the cabinet enclosure;
override one or more current operating conditions based on the operating mode; and
cause the cabinet enclosure to operate according to the operating mode.

18. The system of clause 17, wherein the condition sensor is a proximity sensor and the one or more current operating conditions includes increasing at least one fan speed.

19. The system of clause 15, wherein the condition sensor is a fan speed sensor, the operating mode is a first fan failure, and the one or more current operating conditions includes increasing a second fan speed.

20. The system of clause 15, wherein the instructions when executed further cause the system to:
select an initial operating condition, for the cabinet enclosure, based on a salient operating parameter and one or more historical operating parameters;
compare the initial operating condition to a current operating condition corresponding to operations using the one or more operating settings including the change;
determine the current operating condition has a higher performance than the initial operating condition; and
replace the initial operating condition with the current operating condition.

The specification and drawings are, accordingly, to be regarded in an illustrative rather than a restrictive sense. It will, however, be evident that various modifications and changes may be made thereunto without departing from the broader spirit and scope of the disclosure as set forth in the claims.

What is claimed is:

1. A computer-implemented method, comprising:
receiving one or more current operating parameters for a cabinet enclosure associated with cooling one or more electronic components;
receiving one or more historical operating parameters corresponding to a desired set of operating parameters based, at least in part, on one or more current conditions of the cabinet enclosure;
determining, based on the desired set of operating parameters, one or more adjustments to the one or more current operating parameters;
applying the one or more adjustments to the one or more current operating papers to cause operation of the cabinet enclosure at one or more updated operating parameters;
determining, for the one or more updated operating parameters, one or more metrics;
comparing the one or more metrics to one or more associated metrics for the desired set of operating parameters;
determining at least one metric of the one or more metrics exceeds at least one associated metric of the one or more associated metrics; and
updating a corresponding operating parameter for the at least one associated metric to correspond to an updated operating parameter corresponding to the at least one metric.

2. The computer-implemented method of claim 1, further comprising:
determining at least a second metric of the one or more metrics is less than a second associated metric of the one or more associated metrics; and
adjusting a second operating parameter associated with the second metric.

3. The computer-implemented method of claim 1, wherein the one or more current conditions correspond to at least one of a desired temperature, a desired air flow rate, a desired cooling capacity, or a desired load.

4. The computer-implemented method of claim 1, wherein the one or more operating parameters correspond to at least one of a cooling fluid flow rate, a valve position, a fan speed, or a differential temperature.

5. The computer-implemented method of claim 1, further comprising:
receiving one or more sensor readers corresponding to the one or more operating conditions.

6. A computer-implemented method, comprising:
receiving sensor data corresponding to a control parameter for a cabinet enclosure;
determining one or more metrics based, at least in part, on at least a portion of the sensor data;
comparing the one or more metrics to one or more threshold operating parameters;
determining the one or more metrics fail to satisfy one or more conditions of the one or more threshold operating parameters;
causing a change in one or more current operating settings associated with the control parameter for the cabinet enclosure;
determining, following a period of time after the change, one or more updated metrics based, at least in part, on at least an updated portion of updated sensor data;
determining the one or more updated metrics satisfy the one or more conditions for the one or more threshold operating parameters; and
causing operation of the cabinet enclosure in accordance with the one or more operating settings including the change.

7. The computer-implemented method of claim 6, wherein the control parameter is at least one of a desired temperature, a desired air flow rate, a desired cooling capacity, or a desired load.

8. The computer-implemented method of claim 6, further comprising:
determining, following a second period of time after the change, one or more second updated metrics based, at least in part, on at least a second updated portion of updated sensor data;
determining the one or more second updated metrics fail to satisfy the one or more conditions for the one or more threshold operating parameters;
determining a remediation limit has been reached; and
providing an alert regarding one or more components associated with the one or more operating settings.

9. The computer-implemented method of claim 8, wherein the alert is at least one of an auditory alarm or a visual alarm.

10. The computer-implemented method of claim 6, further comprising:
receiving second sensor data corresponding to a condition sensor;
determining, based on the second sensor data, an operating mode for the cabinet enclosure;
overriding one or more current operating conditions based on the operating mode; and
causing the cabinet enclosure to operate according to the operating mode.

11. The computer-implemented method of claim 10, wherein the condition sensor is a proximity sensor and the one or more current operating conditions includes increasing at least one fan speed.

12. The computer-implemented method of claim 10, wherein the condition sensor is a fan speed sensor, the operating mode is a first fan failure, and the one or more current operating conditions includes increasing a second fan speed.

13. The computer-implemented method of claim 6, further comprising:
receiving a plurality of sensor data over a period of time for a plurality of different associated cabinet components;
training one or more machine learning systems based, at least in part, on the plurality of sensor data; and
inferring, based on an input salient operating parameter using the trained one or more machine learning systems, one or more suggested operating parameters for the cabinet enclosure.

14. The computer-implemented method of claim 6, further comprising:
selecting an initial operating condition, for the cabinet enclosure, based on a salient operating parameter and one or more historical operating parameters;
comparing the initial operating condition to a current operating condition corresponding to operations using the one or more operating settings including the change;
determining the current operating condition has a higher performance than the initial operating condition; and
replacing the initial operating condition with the current operating condition.

15. A system, comprising:
at least one processor; and
memory including instructions that, when executed by the at least one processor, cause the system to:
receive sensor data corresponding to a control parameter for a cabinet enclosure;
determine one or more metrics based, at least in part, on at least a portion of the sensor data;
compare the one or more metrics to one or more threshold operating parameters;
determine the one or more metrics fail to satisfy one or more conditions of the one or more threshold operating parameters;
cause a change in one or more current operating settings associated with the control parameter for the cabinet enclosure;
determine, following a period of time after the change, one or more updated metrics based, at least in part, on at least an updated portion of updated sensor data;
determine the one or more updated metrics satisfy the one or more conditions for the one or more threshold operating parameters; and
cause operation of the cabinet enclosure in accordance with the one or more operating settings including the change.

16. The system of claim 15, wherein the control parameter is at least one of a desired temperature, a desired air flow rate, a desired cooling capacity, or a desired load.

17. The system of claim 15, wherein the instructions when executed further cause the system to:
receive second sensor data corresponding to a condition sensor;
determine, based on the second sensor data, an operating mode for the cabinet enclosure;
override one or more current operating conditions based on the operating mode; and
cause the cabinet enclosure to operate according to the operating mode.

18. The system of claim 17, wherein the condition sensor is a proximity sensor and the one or more current operating conditions includes increasing at least one fan speed.

19. The system of claim 15, wherein the condition sensor is a fan speed sensor, the operating mode is a first fan failure, and the one or more current operating conditions includes increasing a second fan speed.

20. The system of claim 15, wherein the instructions when executed further cause the system to:
select an initial operating condition, for the cabinet enclosure, based on a salient operating parameter and one or more historical operating parameters;
compare the initial operating condition to a current operating condition corresponding to operations using the one or more operating settings including the change;
determine the current operating condition has a higher performance than the initial operating condition; and
replace the initial operating condition with the current operating condition.
